(19) United States
(12) Patent Application Publication
(10) Pub. No.: US 2017/0084426 A1
(43) Pub. Date: Mar. 23, 2017

(54) APPARATUS FOR DETERMINING PROCESS RATE

(71) Applicant: Lam Research Corporation, Fremont, CA (US)

(72) Inventors: Luc Albarede, Fremont, CA (US); Yassine Kabouzi, Fremont, CA (US)

(21) Appl. No.: 14/863,211

(22) Filed: Sep. 23, 2015

(51) Int. Cl. H01J 37/32

(52) U.S. Cl. CPC H01J 37/3244; H01J 37/32009; H01J 37/32715; H01J 37/32834; H01J 2237/334

(57) ABSTRACT

An apparatus for processing a substrate is provided. A substrate support is located within a processing chamber. A gas inlet provides a process gas into the processing chamber. An exhaust pump pumps gas from the processing chamber. A gas byproduct measurement system comprises an IR light source and an IR detector. A controller comprises at least one processor and computer readable media. The computer readable media comprises computer readable code for flowing the process gas into the etch chamber, for processing data from the IR detector, for using the processed data from the IR detector for determining concentration of the gas byproduct, and for using the determined concentration of the gas byproduct for adjusting the flow of the process gas into the processing chamber.

### CROSS REFERENCE TO RELATED APPLICATIONS

The present disclosure incorporates by reference the patent entitled, “METHOD AND APPARATUS FOR DETERMINING PROCESS RATE” by Kabouzi et al. filed on Sep. 23, 2015 as U.S. Pat. No. 14/862,983, which is incorporated by reference for all purposes.

### BACKGROUND

The present disclosure relates to the manufacturing of semiconductor devices. More specifically, the disclosure relates to etching used in manufacturing semiconductor devices.

During semiconductor wafer processing, silicon containing layers are selectively etched.

### SUMMARY

To achieve the foregoing and in accordance with the purpose of the present disclosure, an apparatus for processing a substrate is provided. A processing chamber is provided. A substrate support is located within the processing chamber. A gas inlet provides a process gas into the processing chamber, wherein when a substrate is processed in the processing chamber the process provides a gas byproduct. A gas source provides the process gas to the gas inlet. An exhaust pump pumps gas from the processing chamber. A gas byproduct measurement system comprises an IR light source and an IR detector. A controller is controllably connected to the gas source and IR light source and receives signals from the IR detector. The controller comprises at least one processor and computer readable media. The computer readable media comprises computer readable code for flowing the process gas into the etch chamber, computer readable code for processing data from the IR detector, computer readable code for using the processed data from the IR detector for determining concentration of the gas byproduct, and computer readable code for using the determined concentration of the gas byproduct for adjusting the flow of the process gas into the processing chamber.

In another manifestation, an apparatus for processing a substrate is provided. A processing chamber is provided. A substrate support is within the processing chamber. A gas inlet provides a process gas into the processing chamber, wherein when a substrate is processed in the processing chamber the process provides a gas byproduct. A gas source provides the process gas to the gas inlet. An exhaust pump pumps gas from the processing chamber. A gas byproduct measurement system comprises an IR light source, a confinement ring surrounding a volume above the substrate support, at least one minor for reflecting IR light within the confinement ring, and an IR detector positioned to receive light from the IR light source after the light is reflected within the confinement ring a plurality of times.

In another manifestation, an apparatus for processing a substrate is provided. A processing chamber is provided. A substrate support is within the processing chamber. A gas inlet provides a process gas into the processing chamber, wherein when a substrate is processed in the processing chamber the process provides a gas byproduct. A gas source provides the process gas to the gas inlet. An exhaust pump pumps gas from the processing chamber. A gas byproduct measurement system comprises a quantum cascade laser for providing IR light, a gas cell, which receives exhaust from the exhaust pump, at least one minor within the gas cell, which is highly reflective on IR light, and an IR detector positioned to receive light from the quantum cascade laser after the light is reflected a plurality of times within the gas cell.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 schematically illustrates an example of a plasma processing chamber.

FIG. 2 is a high level block diagram showing a computer system, which is suitable for implementing a controller.

FIG. 3 is a more detailed schematic view of the gas cell of the embodiment, shown in FIG. 1.

FIG. 4 is a high level flow chart of a process used in an embodiment.

FIG. 5 is a more detailed flow chart of the step of using the measured concentration to determine processing rate.

FIG. 6 is a top view of a processing tool.

FIG. 7 is a schematic view of detection and control system for the processing tool.

FIG. 8 is a schematic view of an etch reactor used in another embodiment.

FIG. 9 is a schematic top view of the plasma volume formed by the confinement shroud (C-shroud).

FIG. 10 is a top view of another embodiment.

FIG. 11 is a top view of another embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Current technology used for process control (e.g. endpoint) relies on relative measurements or indirect measurements of plasma parameters using emission spectroscopy, reflectance, or RF voltage and current. For endpoint control, optical emission spectroscopy reaches it limits with signal changes tending to zero when CDs shrink below 21 nm and aspect ratio increases beyond 30:1. For in-situ etch rate (ER) measurements using RF voltage/current are based on correlations that are not always maintained chamber to chamber.

An embodiment relies on absolute measurements of SiF₄ or SiBr₄, or SiCl₄ or other SiX₄ byproducts that is a direct byproduct of most silicon containing etches (nitrides, oxides, poly, and silicon films) when using fluorocarbon based chemistries. By combining the measurement with an etch model (SiF₄ mass balance based on XSEM images or a feature profile simulation model calibrated with XSEM images), one can predict endpoint, ER as a function of depth, average wafer selectivity, and uniformity in certain conditions. The SiF₄ byproducts are detected using IR absorption using quantum cascade laser spectroscopy allowing parts per billion level detection for accurate predictions.

This discloser describes a method that combines etch-profile modeling coupled with SiF₄ IR-absorption to control the etch process. The method allows the extension of endpoint capability beyond the reach of tradition methods, such as emission spectroscopy, in high-aspect ratio applications such as DRAM cell-etch and 3D-NAND hole and trench patterning. The combination of absolute density measurement and etch profile emission modeling allows one to additionally determine in-situ etch process parameters such as ER, selectivity, and uniformity that can be used to achieve run-to-run process matching.

In an embodiment, an etch process is characterized by measuring a direct stable byproduct that can be used to determine: 1) Endpoint for high-aspect ratio DRAM and 3D-NAND etches for process/CD control, 2) Method to scale endpoint detection for future nodes, 3) Combined with a model one can determine in-situ: a) Average wafer ER and ER as function of depth (ARDE), b) An average wafer uniformity and selectivity, and c) Both measurements can be used for run-to-run matching and fault detection, 4) Using high sensitivity quantum cascade laser spectroscopy to achieve ppb level limit of detection needed for accurate etch endpoint and etch parameters estimation.

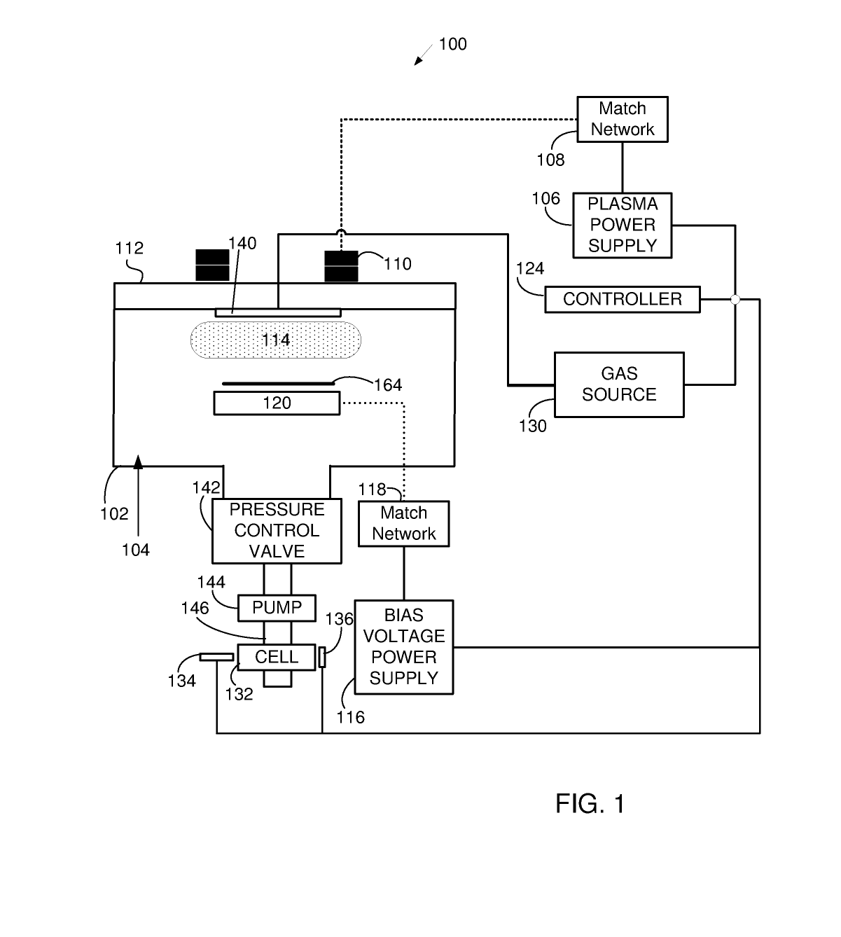

FIG. 1 schematically illustrates an example of a plasma processing chamber 100, which may be used to perform the process of etching a silicon containing layer in accordance with one embodiment. The plasma processing chamber 100 includes a plasma reactor 102 having a plasma processing confinement chamber 104 therein. A plasma power supply 106, tuned by a match network 108, supplies power to a TCP coil 110 located near a power window 112 to create a plasma 114 in the plasma processing confinement chamber 104 by providing an inductively coupled power. The TCP coil (upper power source) 110 may be configured to produce a uniform diffusion profile within the plasma processing confinement chamber 104. For example, the TCP coil 110 may be configured to generate a toroidal power distribution in the plasma 114. The power window 112 is provided to separate the TCP coil 110 from the plasma processing confinement chamber 104 while allowing energy to pass from the TCP coil 110 to the plasma processing confinement chamber 104. A wafer bias voltage power supply 116 tuned by a match network 118 provides power to an electrode 120 to set the bias voltage on the substrate 104 which is supported by the electrode 120. A controller 124 sets points for the plasma power supply 106, gas source/gas supply mechanism 130, and the wafer bias voltage power supply 116.

The plasma power supply 106 and the wafer bias voltage power supply 116 may be configured to operate at specific radio frequencies such as, for example, 13.56 MHz, 27 MHz, 2 MHz, 60 MHz, 200 kHz, 2.54 GHz, 400 kHz, and 1 MHz, or combinations thereof. Plasma power supply 106 and wafer bias voltage power supply 116 may be appropriately sized to supply a range of powers in order to achieve desired process performance. For example, in one embodiment, the plasma power supply 106 may supply the power in a range of 50 to 5000 Watts, and the wafer bias voltage power supply 116 may supply a bias voltage of in a range of 20 to 2000 V. For a bias up to 4 kV or 5 kV a power of no more than 25 kW is provided. In addition, the TCP coil 110 and/or the electrode 120 may be comprised of two or more sub-coils or sub-electrodes, which may be powered by a single power supply or powered by multiple power supplies.

As shown in FIG. 1, the plasma processing chamber 100 further includes a gas source/gas supply mechanism 130. The gas source 130 is in fluid connection with plasma processing confinement chamber 104 through a gas inlet, such as a shower head 140. The gas inlet may be located in any advantageous location in the plasma processing confinement chamber 104, and may take any form for injecting gas. Preferably, however, the gas inlet may be configured to produce a “tunable” gas injection profile, which allows independent adjustment of the respective flow of the gases to multiple zones in the plasma process confinement chamber 104. The process gases and byproducts are removed from the plasma process confinement chamber 104 via a pressure control valve 142 and a pump 144, which also serve to maintain a particular pressure within the plasma processing confinement chamber 104. The gas source/gas supply mechanism 130 is controlled by the controller 124. A Kiyo by Lam Research Corp. of Fremont, Calif., may be used to practice an embodiment. In other examples, a Flex by Lam Research Corp. of Fremont, Calif., may be used to practice an embodiment.

In this embodiment, connected to an exhaust pipe 146 after the pump 144, a gas cell 132 is provided, into which exhaust gas flows. An IR light source 134 is positioned adjacent to a window in the gas cell 132, so that an IR beam from the IR light source 134 is directed into the gas cell 132. The IR beam can travel through the gas cell multiple times (typically for a distance greater than 1 m) to achieve ppb level or even lower hundredth of ppt detection limits. The IR light is absorbed by the gas as it travels inside the gas cell. An IR detector 136 is positioned adjacent to another window in the gas cell 132 to measure the light absorption level.

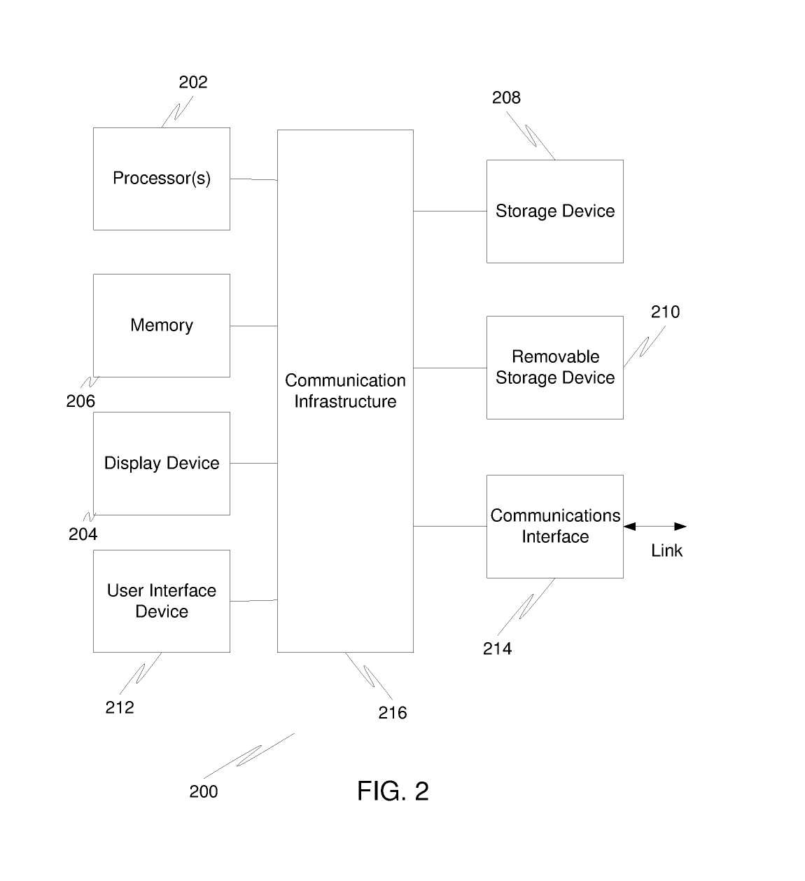

FIG. 2 is a high level block diagram showing a computer system 200, which is suitable for implementing a controller 124 used in embodiments. The computer system may have many physical forms ranging from an integrated circuit, a printed circuit board, and a small handheld device up to a huge super computer. The computer system 200 includes one or more processors 202, and further can include an electronic display device 204 (for displaying graphics, text, and other data), a main memory 206 (e.g., random access memory (RAM)), storage device 208 (e.g., hard disk drive), removable storage device 210 (e.g., optical disk drive), user interface devices 212 (e.g., keyboards, touch screens, keypads, mice or other pointing devices, etc.), and a communication interface 214 (e.g., wireless network interface). The communication interface 214 allows software and data to be transferred between the computer system 200 and external devices via a link. The system may also include a communications infrastructure 216 (e.g., a communications bus, cross-over bar, or network) to which the aforementioned devices/modules are connected.

Information transferred via communications interface 214 may be in the form of signals such as electronic, electromagnetic, optical, or other signals capable of being received by communications interface 214, via a communication link that carries signals and may be implemented using wire or cable, fiber optics, a phone line, a cellular phone link, a radio frequency link, and/or other communication channels. With such a communications interface, it is contemplated that the one or more processors 202 might receive information from a network, or might output information to the network in the course of performing the above-described method steps. Furthermore, method embodiments may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

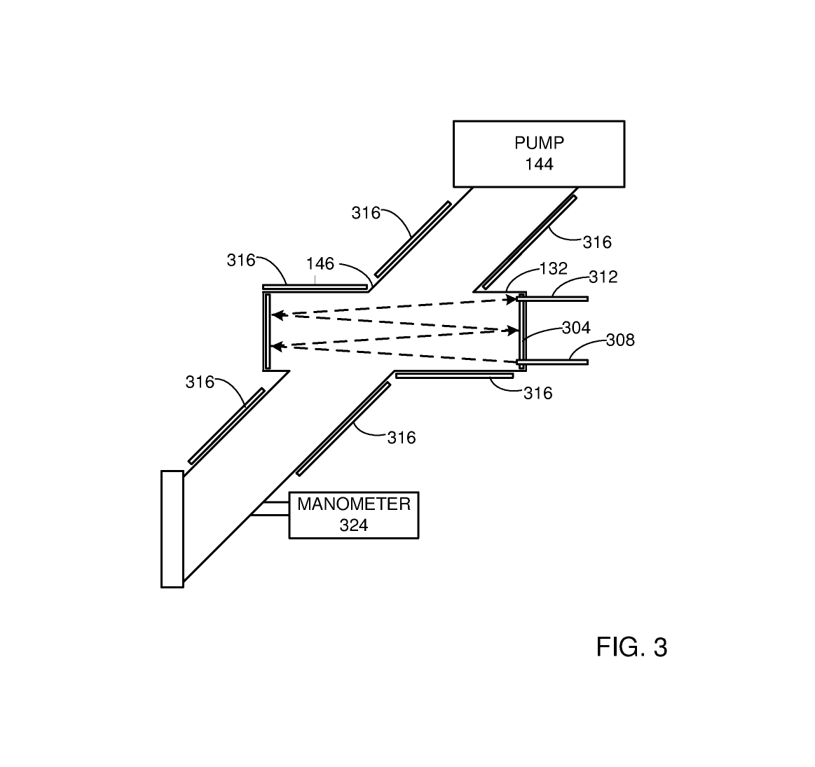

FIG. 3 is a more detailed schematic view of the gas cell 132 of the embodiment, shown in FIG. 1. The exhaust pipe 146 extends from the output of pump 144. In this example, the exhaust pipe 146 extends at an approximate 45° angle from the pump 144. The gas cell 132 is part of the exhaust pipe 146. The gas cell 132 comprises one or two spherical minors 304 that are within the outer walls of the gas cell 132. An input fiber 308 is optically connected between the IR light source, which in this embodiment is a quantum cascade laser (QCL), and the interior of the gas cell 132. An output fiber 312 is optically connected between the IR detector and the interior of the gas cell 132. Heaters 316 are placed around surfaces of the exhaust pipe 146 and gas cell 132. One or more of the heaters 316 may have heat sensors. The heaters 316 may be electrically connected to and controlled by the controller and may provide temperature data to the controller. A manometer 324 is connected to the exhaust pipe 146. Monometer and temperature measurements may be used to make absolute calibration measurements of SiF₄. For foreline measurements, control of the N₂ purge of the turbopump is needed, which would require a highly accurate mass flow controller of the flow of N₂, with a range of 100-1000 sccm.

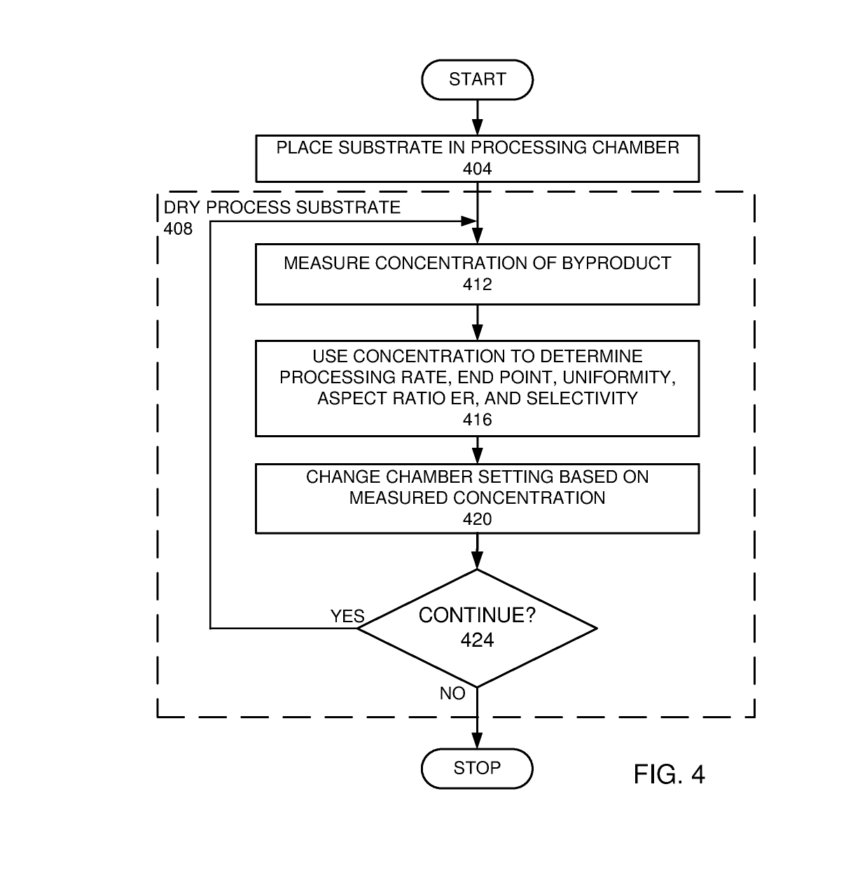

To facilitate understanding, FIG. 4 is a high level flow chart of a process used in an embodiment. A substrate is placed in a processing chamber (step 404). The substrate is dry processed (step 408). During the dry processing a gas byproduct is created. The concentration of the gas byproduct is measured (step 412). The measured concentration of the gas byproduct is used to determine processing rate, endpoint, uniformity, aspect ratio dependent etch rate, and selectivity (step 416). Chamber settings are changed based on the measured concentration of the gas byproduct (step 420). A determination is made on whether the dry process is complete (step 424). If the dry process is not complete the dry processing of the substrate 408 is continued by further measuring the concentration of the byproduct and continuing the cycle. If the dry process is complete, then the process is stopped.

### EXAMPLES

In an example of a preferred embodiment, a substrate with a silicon containing layer is placed in a processing chamber (step 104).

A dry process is performed on the substrate in the processing chamber, where the dry process creates at least one gas byproduct (step 408). In different embodiments, either the substrate is a silicon wafer, which is etched, or one or more silicon containing layers over the substrate are etched. In this example, a stack of alternating silicon oxide and silicon nitride layers is etched. Such an alternating stack of silicon oxide and silicon nitride is designated as ONON, which is used in 3D memory devices. In this example, there are at least eight alternating layers of ONON. In other embodiments, alternating layers of silicon oxide and polysilicon (OPOP) may be etched. In etching such a stack, both ER and selectivity decrease with aspect ratio, meaning that the difference between etch rates of the silicon oxide and silicon nitride decreases as aspect ratio, the ratio of the etch depth over the etch width, increases. To etch such a stack an etch gas of CₓF_{y}H_{z}/O₂ is provided by the gas source 130. RF power is provided by the plasma power supply 106 to the TCP coil 110 to form the etch gas into an etch plasma, which etches the stack and forms at least one gas byproduct, which in this example is SiF₄. (Other etch byproducts such as SiBr₄ or SiCl₄ can be monitored depending on the gas chemistry by tuning the IR light source to the absorption band of each byproduct.)

During the dry process, the concentration of the at least one gas byproduct is measured (step 412). In this embodiment, exhaust from the pump 144 flows to the gas cell 132. The IR light source 134 provides a beam of IR light into the gas cell 132. In this embodiment, sides of gas cell 132 reflect the beam of IR light a plurality of times before the beam of IR light is directed to the IR detector 136, which measures the intensity of the beam of IR light. Data from the IR detector 136 is sent to the controller 124, which uses the data to determine the concentration of the SiF₄.

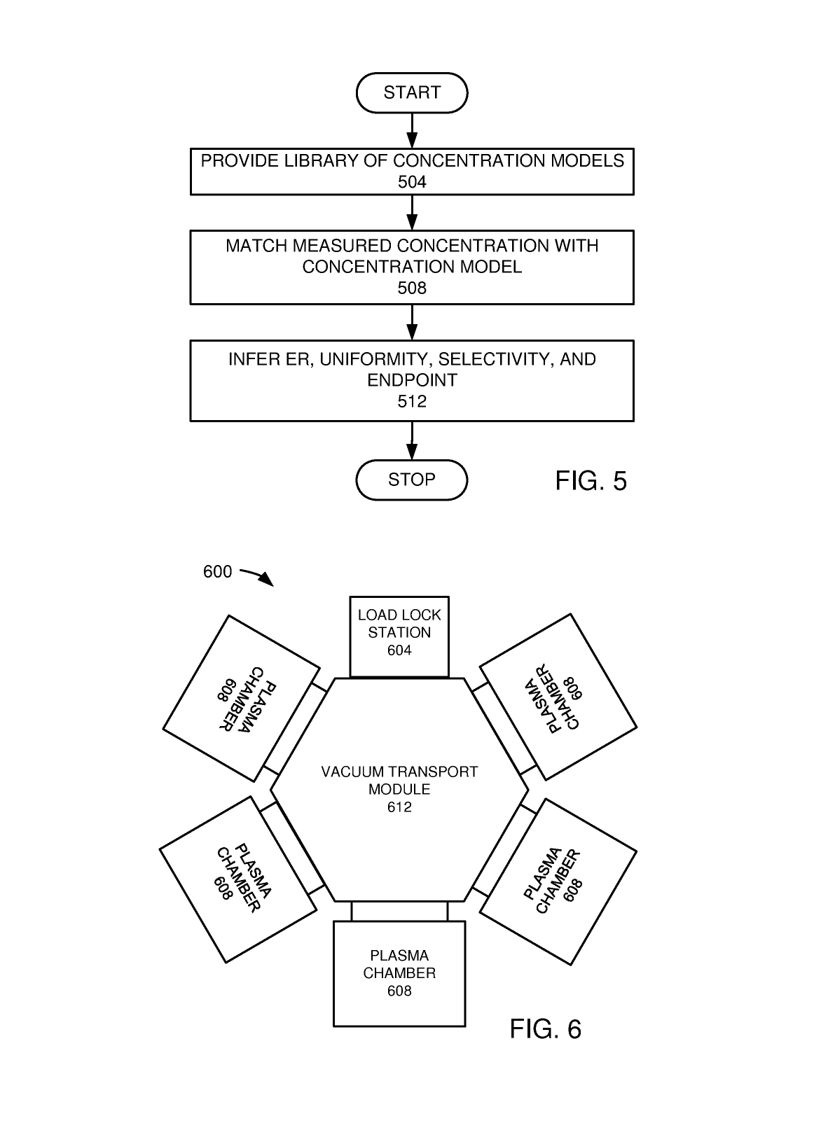

The measured concentration is used to determine processing rate, endpoint, uniformity, and selectivity (step 416). FIG. 5 is a more detailed flow chart of the step of using the measured concentration to determine processing rate. A library of concentration models is provided (step 504). Such models may provide feature/wafer scale etch as a function of aspect ratio, uniformity, and selectivity. Such models may be generated by experiment or may be analytically calculated, or may be determined using both methods. In an example of a creation of a model, an etch may be provided where concentration of a gas byproduct is measured over time. Since this example uses an etch, the processing rate is an etch rate. The etched features are examined and measured. From the measurements of the features and the measurement of the concentration of byproduct gas over time geometrical etch models and mass balanced equations may be used to determine etch rate, endpoint, uniformity, and selectivity. In one embodiment, a model would have a single concentration. In another embodiment, a model has a plurality of concentrations at various times. A plurality of measured concentrations over time is then used to match the closest model (step 508). The closest model is then used to determine an etch rate (step 512). The etch rate is the increase in the depth of etched features over time. To determine etch rate, endpoint, uniformity, and selectivity either a single measurement or a plurality of measurements may be used. The endpoint indicates when an etch is complete. This is may be determined by when a stop layer is reached or a discontinuity in the signal is reached. As mentioned above, the aspect ratio is the ratio of the etch depth over the etch width. The measured concentration may be used to determine the evolution of ER and selectivity with aspect ratio of the etched features since CD evolution of the feature is extracted from the model. Uniformity is a measurement of how evenly features are being etched. Features may be etched at different rates depending on feature width or feature density, causing nonuniform etch rates. The measured concentration may be used to determine the uniformity of the etch rates. Selectivity is a measurement of the difference in the etch rate of one material versus the etch rate of another material. In this example, the selectivity may be the difference in the etch rate of silicon oxide compared to silicon nitride. In the alternative, selectivity may be the different in the etch rate of the silicon oxide compared to the etch rate of a mask material or a stop layer. The measured concentration may be used to determine etch selectivity.

Chamber settings are changed based on the measured concentration (step 420). When the endpoint is not found using the measured concentration (step 424), the etch process is continued and the process is continued back at step 412. If the etch stop is found, the etch may be stopped by stopping the flow of the etch gas or by stopping the power from the plasma power supply 406 or both. If it is determined that the ER is too low, etch parameters such as gas or RF power may be changed to increase ER. If it is determined that the nonuniformity is too high, parameters such as gas feed to different region the chamber or ESC zones temperatures may be changed to improve uniformity.

The heaters 316 are used to maintain the walls of the exhaust pipe 146 and gas cell 132 at a temperature of 120° C. The heating prevents or reduces deposition on the walls of the exhaust pipe 146. Reducing or eliminating the deposition on the walls of the exhaust pipe keeps the flow area of the exhaust pipe 146 and the pressure in the exhaust pipe 146 more constant, which allows for a more accurate reading. The heating may also prevent or reduce deposition on the spherical mirror 304. Eliminating or reducing deposition on the spherical minor 304 prevents or reduces reflective interference caused by the deposition. The position of the input fiber 308 and output fiber 312 and the position and shape of the spherical mirror 304 allows for an IR beam to be reflected by the spherical minor 304 a plurality of times causing the IR beam to transverse the gas cell a plurality of time to pass from the input fiber 308 to the output fiber 312, thus allowing for sub ppb level limit of detection. The manometer 324 is also connected to the controller 124. The pressure measurements provided by the manometer 324 may be used in calculating the concentration of the byproduct. As shown, the spherical minor 304 and the incident angle of the input fiber 308 may be placed so that each reflection is at a higher location, forming a vertical zigzag (as shown), until the output fiber 312 is reached by the reflected IR beam.

FIG. 6 is a top view of a processing tool 600 and which includes a plurality of plasma processing chambers, used in an embodiment. A load lock station 604 operates to transfer the wafer back and forth between the atmosphere and a vacuum of a vacuum transport module (VTM) 612. The VTM 612 is part of the processing tool 600 and connects to a plurality of plasma processing chambers 608. The plasma processing chambers 608 may provide the same process or different processes. In this embodiment, a single QCL may be used for all five plasma processing chambers 608. Other embodiments may support another number of plasma processing chambers, such as supporting six plasma processing chambers.

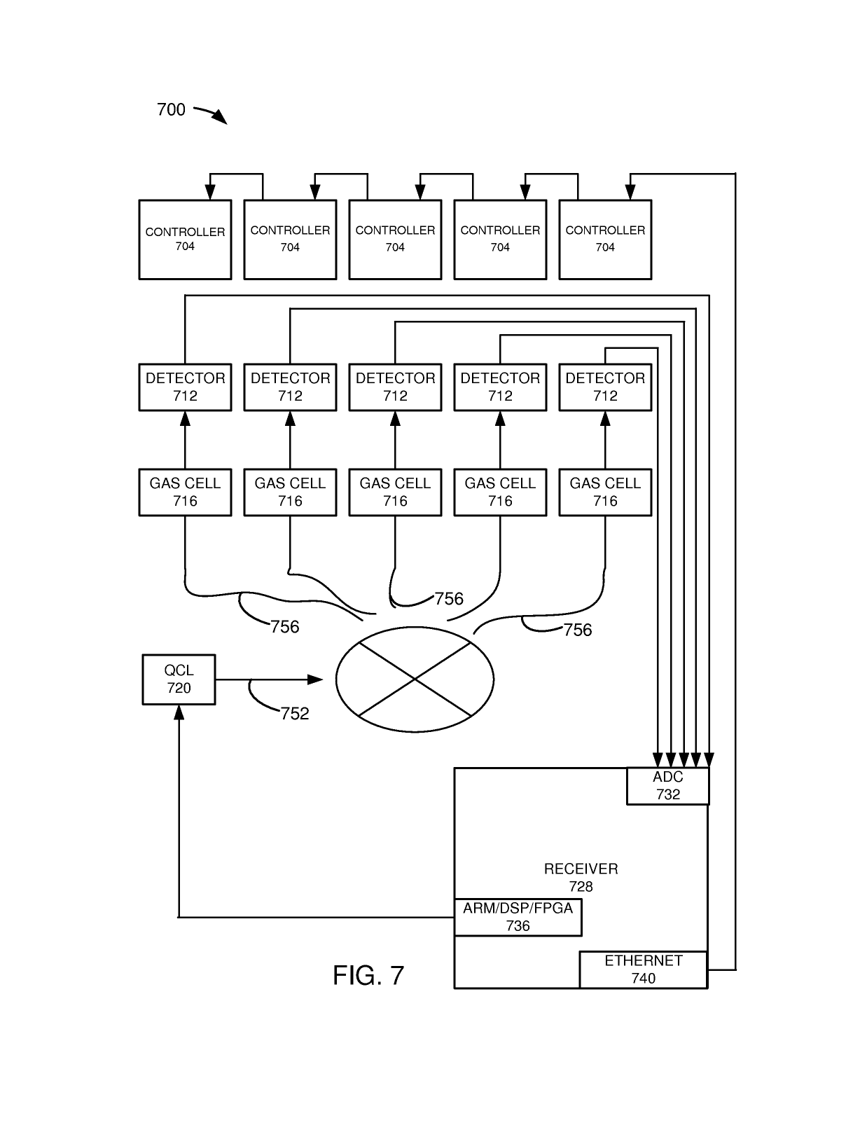

FIG. 7 is a schematic view of detection and control system 700 for the processing tool with a concentration detection system with a single QCL 720. The QCL 720 provides an IR laser beam 752 directed to ends of optical fibers 756, which splits the IR laser beam 752. The optical fibers 756 direct IR laser beams to gas cells 716. A separate detector 712 is associated with a plasma processing chamber, so that each plasma processing chamber has a dedicated detector 712. Each detector 712 receives an IR laser beam that has been reflected a plurality of times in a gas cell 716. The output from the detectors 712 is provided to an analog to digital converter (ADC) 732 of a receiver 728. The receiver may have an ARM, DSP, or FPGA system 736 that may be connected to the QCL, in order to control the QCL to tune to different wavelengths. In this example, the system 736 causes the QCL to cycle through a range of wavelengths in order to scan byproducts absorption band and deduce its concentrations. The receiver 728 may also have an Ethernet device 740, which would be used to network with controllers 704. The controllers 704 are the same as the controller 124 in FIG. 1, used to control various parts of the plasma processing chamber 100. In this embodiment, each plasma processing chamber 100 has a dedicated controller 704. In other embodiments, a controller may be used to control more than one plasma processing chamber. This embodiment allows improved detection at a lower cost, since a single QCL is needed for several chambers. The use of a single QCL is much lower than requiring five QCL's. The limitation of sharing the QCL between the different chambers is due to the saturation level of the detectors. The use of a higher power QCL allows the use of the QCL with a higher number of chambers.

Advantages of placing the gas cell right after the exhaust pump are that the gas is denser, in after the exhaust pump than the gas in the processing chamber, and latency or measurement lag is at a minimal. In addition, reflective surfaces are not exposed to the plasma in the processing chamber, so that reflective surfaces would not be degraded by the plasma. The gas cell body and mirrors are heated up to 120° C. to reduce polymer and particles deposition on their internal walls, which would results in a performance reduction of the sensor detection limit. Also, N₂ gas purge can be flowed around the mirrors to minimize gas contact and deposition. Additional coatings, such as MgF₂, can be deposited on the mirrors to protect them from being etched by acid byproducts such as HF during processing or during chamber venting.

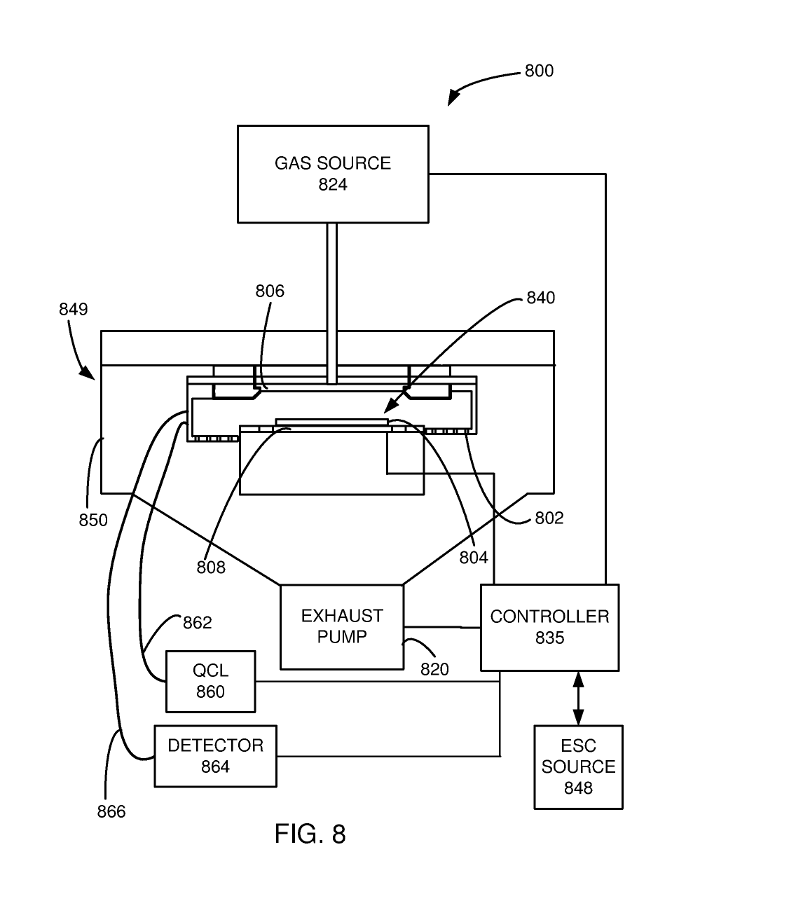

In other embodiments, the gas cell is in the plasma processing chamber, such as surrounding the plasma region. FIG. 8 is a schematic view of an etch reactor that may be used in practicing such an embodiment. An etch reactor 800 comprises a gas distribution plate 806 providing a gas inlet and a chuck 808, within an etch chamber 849, enclosed by a chamber wall 850. Within the etch chamber 849, a substrate 804 on which the stack is formed is positioned on top of the chuck 808. The chuck 808 may provide a bias from the ESC source 848 as an electrostatic chuck (ESC) for holding the substrate 804 or may use another chucking force to hold the substrate 804. A gas source 824 is connected to the etch chamber 849 through the distribution plate 806. A plasma confinement shroud, which in this embodiment is a C-shroud 802, surrounds the plasma volume. A QCL laser 860 and an IR detector 864 are controllably connected to the controller 835. First and second optical fibers 862 and 866 are optically connected between the interior of the C-shroud 802 and the QCL laser 860 and IR detector 864 respectively. In this example, the plasma is generated using capacitive coupling. A Flex by Lam Research Corp. of Fremont, Calif., may be used to practice an embodiment with capacitive coupling to etch DRAM and 3D NAND structures. In other embodiments other power coupling systems may be used. The QCL laser 860 has a tuning range that will cover more than the band for SiF₄ IR band and the extra tuning may be used to detect any deposition like a CₓF_{y} polymer deposition, so that the laser can monitor SiF₄ peak and at the same time other film peak and track the level of deposition on the mirrors and windows and the gas cell. These measurements may be used for tracking the status of the optical system to determine maintenance of the system and robustness of the measurements.

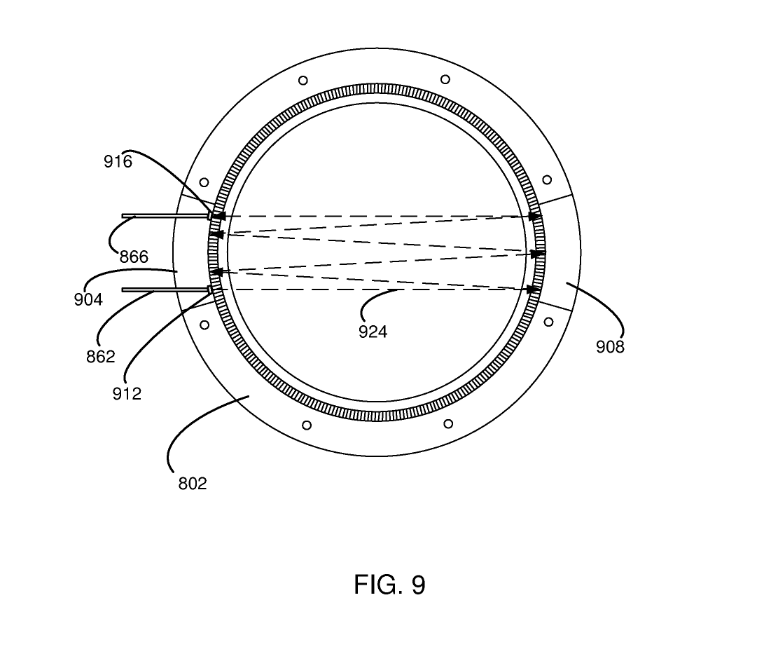

FIG. 9 is a schematic top view of the plasma volume formed by the C-shroud 802. A first concaved mirror 904 is formed on one side of the C-shroud, and a second concaved mirror 908 is formed on a second side of the C-shroud opposite the first concaved mirror 904. In this embodiment, the first mirror is connected to the first and second optical fibers 862, 866 and provides first and second windows 912, 916 to allow IR light beam 924 to pass into the plasma volume and out of the plasma volume. In this embodiment, IR light beam 924 from the QCL passes through the first optical fiber 862, enters the plasma volume through the first window 912, is reflected a plurality of times between the first and second concaved mirrors 904, 908, passes through the second window 916 to the second optical fiber 866, and then to the IR detector.

In one embodiment, the C-shroud is polysilicon. The first and second concaved mirrors 904, 908 may be highly polished portions of the C-shroud, where the curvature is set to meet the required concavity. Windows are formed in the surface of the C-shroud.

Providing the detection within the plasma volume reduces measurement lag time. However, concentrations of gases within the plasma volume are much lower than concentrations of gases in the exhaust. This may be partially compensated by increasing the length of the light path. In addition, the plasma may more quickly degrade the reflective surfaces and windows.

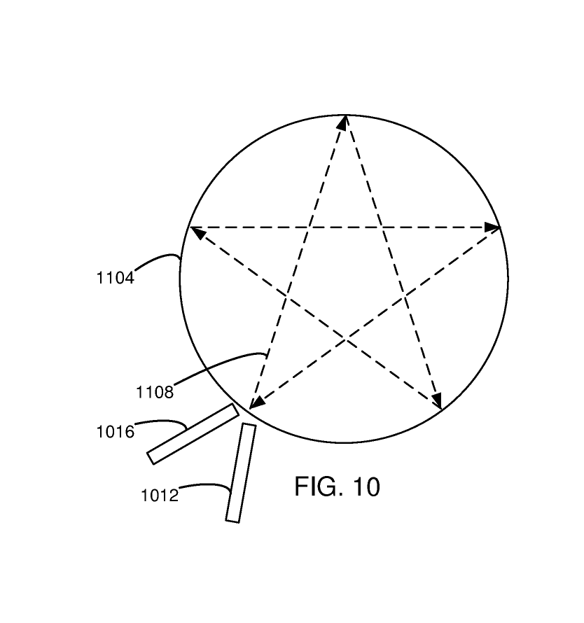

FIG. 10 is a top view of another embodiment. This embodiment shows an enclosure 1004 with a circular cross section. The enclosure may be a C-shroud around a plasma volume or a gas cell around a volume of exhaust gas after the exhaust pump. In various embodiments and claims the term “gas cell” includes a volume of gas within an enclosure, such as gas cell 132 or a volume of plasma in an enclosure such as the volume of plasma within the C-shroud. In this example, either the entire circular surface is reflective, or a plurality of minors is located around the circumference of the circular surface. In this embodiment, the IR beam 1008 forms a star shape pattern in going from a first optical fiber 1012 to a second optical fiber 1016. In other embodiments, the light path may be directed by a toroidal minor configuration along the perimeter of the C-shroud. The number of reflections on the C-shroud is controlled by the input angle of the light, and the light path may have a star polygon shape. The C-shroud may be a dielectric part, which may be reflective, or may have a reflective liner.

Other star shaped paths, such as eight or ten pointed stars may be used to increase the path length. In other embodiments, a vertical path, such as shown in FIG. 3 may be combined with a star path, to create a helical path.

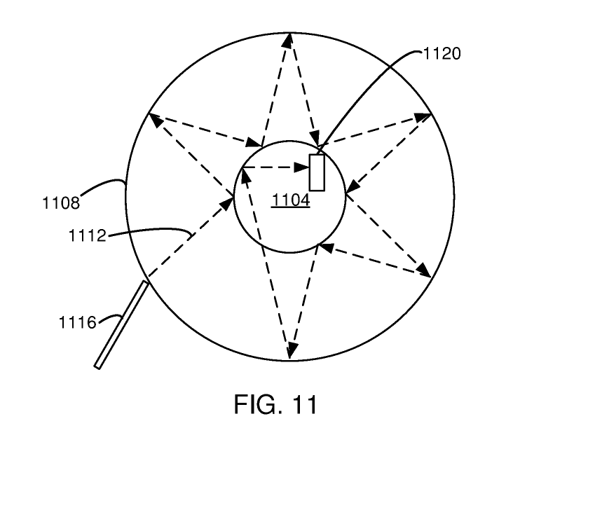

FIG. 11 is a top view of another embodiment, which places an inner circular reflective minor 1104 at the center of an outer circular reflective mirror 1108. In this example, a detector 1120 is placed inside the inner circular reflective mirror 1104. In this embodiment, the IR light beam 1112 is reflected between the inner circular reflective mirror 1104 and the outer circular reflective minor 1108 in a star shape pattern from the first optical fiber 1116 to a window in the inner circular reflective minor 1104 and then to the detector 1120. This embodiment provides a foreline measurement and provides a more compact gas cell.

In another embodiment, the plasma may be measured remotely from the chamber.

Various embodiments are useful for providing memory devices such as DRAM and 3D-NAND devices. In various embodiments the plasma process is an etch process of a silicon containing layer or a low-k dielectric layer. In various embodiments the RF power may be inductively coupled or capacitively coupled. In other embodiments, alternating layers of silicon oxide and polysilicon (OPOP) may be etched.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. An apparatus for processing a substrate, comprising
a processing chamber;
a substrate support within the processing chamber;
a gas inlet for providing a process gas into the processing chamber, wherein when a substrate is processed in the processing chamber the process provides a gas byproduct;
a gas source for providing the process gas to the gas inlet;
an exhaust pump for pumping gas from the processing chamber;
a gas byproduct measurement system, comprising:
an IR light source; and
an IR detector; and
a controller controllably connected to the gas source and IR light source and which receives signals from the IR detector, wherein the controller comprises:
at least one processor; and
computer readable media, comprising:
computer readable code for flowing the process gas into the etch chamber;
computer readable code for processing data from the IR detector;
computer readable code for using the processed data from the IR detector for determining concentration of the gas byproduct; and
computer readable code for using the determined concentration of the gas byproduct for adjusting the flow of the process gas into the processing chamber.

2. The apparatus, as recited in claim 1, further comprising computer readable code for using the determined concentration of the gas byproduct for determining processing rate and endpoint.

3. The apparatus as recited in claim 2, further comprising memory storing a plurality of models related to processing rate and endpoint, wherein the computer readable code for using the processed data, comprises computer readable code for comparing the processed data with the plurality of models to find a closest match model, wherein the closest match model indicates processing rate and endpoint.

4. The apparatus as recited in claim 3, further comprising a gas cell, with reflective minors which reflect light from the IR light source a plurality of times through the gas cell before light from the IR light source reaches the IR detector.

5. The apparatus, as recited in claim 4, wherein the IR light source is a quantum cascade laser.

6. The apparatus, as recited in claim 5, wherein the gas cell receives gas from the exhaust pump.

7. The apparatus, as recited in claim 5, wherein the gas cell is a confinement ring surrounding a process volume above the substrate support.

8. The apparatus, as recited in claim 4, wherein the reflective mirrors are formed by sides of the gas cell.

9. The apparatus as recited in claim 1, further comprising:
a second processing chamber;
a second substrate support within the second processing chamber;
a second gas inlet for providing the process gas into the second processing chamber;
wherein the gas byproduct measurement system, further comprises:
a second IR detector, associated with the second processing chamber, wherein the IR detector is associated with the processing chamber; and
a beam splitter which directs part of a beam from the IR light source to the IR detector and part of the beam from the IR light source to the second IR detector; and wherein the controller receives signals from the second IR detector.

10. The apparatus as recited in claim 1, further comprising memory storing a plurality of models related to processing rate and endpoint, wherein the computer readable code for using the processed data, comprises computer readable code for comparing the processed data with the plurality of models to find a closest match model, wherein the closest match model indicates processing rate and endpoint.

11. The apparatus as recited in claim 1, further comprising a gas cell, with reflective minors which reflect light from the IR light source a plurality of times through the gas cell before light from the IR light source reaches the IR detector.

12. The apparatus, as recited in claim 11, wherein the gas cell receives gas from the exhaust pump.

13. The apparatus, as recited in claim 11, wherein the gas cell is a confinement ring surrounding a process volume above the substrate support.

14. The apparatus, as recited in claim 11, wherein the reflective mirrors are formed by sides of the gas cell.

15. The apparatus, as recited in claim 1, wherein the IR light source is a quantum cascade laser.

16. An apparatus for processing a substrate, comprising
a processing chamber;
a substrate support within the processing chamber;
a gas inlet for providing a process gas into the processing chamber, wherein when a substrate is processed in the processing chamber the process provides a gas byproduct;
a gas source for providing the process gas to the gas inlet;
an exhaust pump for pumping gas from the processing chamber;
a gas byproduct measurement system, comprising:
an IR light source;
a confinement ring surrounding a volume above the substrate support;
at least one minor for reflecting IR light within the confinement ring; and
an IR detector positioned to receive light from the IR light source after the light is reflected within the confinement ring a plurality of times.

17. The apparatus, as recited in claim 16, wherein the IR light source is a quantum cascade laser, and wherein the at least one minor is a reflective surface of the confinement ring.

18. An apparatus for processing a substrate, comprising
a processing chamber;
a substrate support within the processing chamber;
a gas inlet for providing a process gas into the processing chamber, wherein when a substrate is processed in the processing chamber the process provides a gas byproduct;
a gas source for providing the process gas to the gas inlet;
an exhaust pump for pumping gas from the processing chamber;
a gas byproduct measurement system, comprising:
a quantum cascade laser for providing IR light;
a gas cell, which receives exhaust from the exhaust pump;
at least one minor within the gas cell, which is reflective on IR light; and
an IR detector positioned to receive light from the quantum cascade laser after the light is reflected a plurality of times within the gas cell.

19. The apparatus, as recited in claim 18, wherein the at least one mirror is a reflective surface of the gas cell.
